(19) United States
(12) Patent Application Publication
(10) Pub. No.: US 2025/0183779 A1
(43) Pub. Date: Jun. 5, 2025

(54) POWER CONVERTER AND CURRENT DETECTION CIRCUIT THEREOF

(71) Applicant: Richtek Technology Corporation, Zhubei City (TW)

(72) Inventors: Tzu-Chen LIN, Zhubei City (TW); Ta-Yung YANG, Taoyuan City (TW); Fu-Ciao SYU, New Taipei City (TW); Kun-Yu LIN, Zhubei City (TW); Yu-Chang CHEN, Jiji Township (TW)

(21) Appl. No.: 18/827,610

(22) Filed: Sep. 6, 2024

Related U.S. Application Data
(60) Provisional application No. 63/604,223, filed on Nov. 30, 2023.

(30) Foreign Application Priority Data
May 29, 2024 (TW) 113119830

(51) Int. Cl. H02M 1/00; G01R 19/00; H02M 3/335

(52) U.S. Cl. CPC H02M 1/0009; G01R 19/0092; H02M 3/33571; H02M 3/33576

(57) ABSTRACT

A power converter includes a high-side transistor, a low-side transistor, a transformer, a first capacitor, a current detection circuit, a second capacitor, and a current detection resistor. The high-side transistor is coupled between an input voltage and a switching node. The low-side transistor is coupled between the switching node and a ground. The transformer includes a primary coil, and is coupled between the switching node and a first node. The first capacitor is coupled between the first node and the ground. The current detection circuit is connected in parallel with the first capacitor, and includes a second capacitor and a current detection resistor. The second capacitor is coupled to the first node. The current detection resistor is coupled between the second capacitor and the ground.

### CROSS REFERENCE TO RELATED APPLICATIONS

This application claims the benefit of U.S. Provisional Application No. 63/604,223, filed on Nov. 30, 2023, the entirety of which is incorporated by reference herein.

This application claims priority of Taiwan Patent Application No. 113119830, filed on May 29, 2024, the entirety of which is incorporated by reference herein.

### BACKGROUND OF THE INVENTION

### Field of the Invention

The disclosure is generally related to a power converter and a current detection circuit thereof.

### Description of the Related Art

Since battery life is a very important factor influencing users' level of satisfaction with their mobile devices, the efficiency of power supplements has become a very important parameter in mobile devices. In addition, the related technologies of switching power converters are constantly being introduced, which has pushed the efficiency of power conversion forward to an unprecedented level.

A flyback voltage converter is a voltage convertor that operates similarly to a buck-boost converter wherein the single coil inductor of the buck-boost converter is replaced with a transformer with two coils and then the rectifying unit (such as a diode) is used to rectify the inductor to generate an output voltage. However, in order to accurately control the flyback voltage converter, it is necessary to detect the current flowing through the primary coil of the transformer. This will achieve the best conversion efficiency of the flyback voltage converter.

### BRIEF SUMMARY OF THE INVENTION

The present invention proposes power converters and current detection circuits thereof. By mirroring a small current path in parallel to a large current path, it not only helps to significantly reduce the power loss caused by the current detection resistor, but also reduces component costs and circuit area. The accuracy of current detection is maintained as well.

In an embodiment, a power converter is provided, which comprises a high-side transistor, a low-side transistor, a transformer, a first capacitor, and a current detection circuit. The high-side transistor is coupled between an input voltage and a switching node. The low-side transistor is coupled between the switching node and a ground. The transformer comprises a primary coil, and the primary coil is coupled between the switching node and a first node. The first capacitor is coupled between the first node and the ground. The current detection circuit is connected in parallel with the first capacitor and comprises a second capacitor and a current detection resistor. The second capacitor is coupled to the first node. The current detection resistor is coupled between the second capacitor and the ground.

According to an embodiment of the present invention, the power converter is an asynchronous half-bridge flyback converter. The power converter acknowledges a current flowing through the transformer and the first capacitor based on a voltage across the current detection resistor.

According to an embodiment of the present invention, a first current flows through the first capacitor, and a second current flows through the second capacitor. A first ratio of the first current to the second current is equal to a second ratio of the first capacitor to the second capacitor. The first current exceeds the second current, and a capacitance value of the first capacitor exceeds a capacitance value of the second capacitor.

According to an embodiment of the present invention, the transformer comprises a first secondary coil.

According to an embodiment of the present invention, the power converter further comprises an output circuit. The output circuit is coupled to the first secondary coil and configured to convert energy stored in the first secondary coil into an output voltage.

According to an embodiment of the present invention, the output circuit comprises a third capacitor and a first rectifying unit. The third capacitor comprises a first terminal and a second terminal and configured to generate an output voltage, wherein the first terminal is coupled to the first secondary coil. The first rectifying unit is coupled between the first secondary coil and the second node and configured to rectify some of energy of the first secondary coil into a third current. The third current charges the third capacitor to generate the output voltage.

According to an embodiment of the present invention, when the high-side transistor is turned on, the low-side transistor is turned off, and the first rectifying unit is turned off, the input voltage stores energy in the transformer and the first capacitor. When the high-side transistor is turned off, the low-side transistor is turned on, and the first rectifying unit is turned on, energy stored in the transformer and the first capacitor is transferred to the first secondary coil through the primary coil to charge the third capacitor to generate the output voltage.

According to another embodiment of the present invention, the transformer further comprises a second secondary coil. The first secondary coil and the second secondary coil are connected in series to a second node.

According to another embodiment of the present invention, the output circuit further comprises a second rectifying unit and a choke. The second rectifying unit is coupled between the second secondary coil and the second terminal and configured to rectify some of energy of the second secondary coil into a fourth current. The choke is coupled between the second node and the first terminal. The fourth current charges the third capacitor to generate the output voltage.

According to an embodiment of the present invention, when the high-side transistor is turned on, the low-side transistor is turned off, and the second rectifying unit is turned on, the input voltage stores energy in the transformer and the first capacitor, and the energy stored in the transformer is transferred to the second secondary coil through the primary coil, so as to charge the third capacitor to generate the output voltage. When the high-side transistor is turned off, the low-side transistor is turned on, and the first rectifying unit is turned on, the energy of the transformer and the first capacitor is transferred to the first secondary coil through the primary coil, so as to charge the third capacitor to generate the output voltage.

In another embodiment, a current detection circuit adapted to a power converter is provided. The power converter comprises a high-side transistor coupled between an input voltage and a switching node, a low-side transistor coupled between the switching node and a ground, a transformer comprising a primary coil, and a first capacitor coupled to the ground. The primary coil is coupled between the switching node and the first capacitor. The current detection circuit comprises a second capacitor and a current detection resistor. The second capacitor is coupled to the first node. The current detection resistor is coupled between the second capacitor and the ground.

According to an embodiment of the present invention, the power converter is an asynchronous half-bridge flyback converter. The power converter acknowledges a current flowing through the transformer and the first capacitor based on a voltage across the current detection resistor.

According to an embodiment of the present invention, a first current flows through the first capacitor, and a second current flows through the second capacitor. A first ratio of the first current to the second current is equal to a second ratio of a capacitance value of the first capacitor to a capacitance value of the second capacitor. The first current exceeds the second current, and the capacitance value of first capacitor exceeds the capacitance value of the second capacitor.

According to an embodiment of the present invention, the transformer comprises a first secondary coil.

According to an embodiment of the present invention, the power converter further comprises an output circuit. The output circuit is coupled to the first secondary coil and configured to convert energy of the first secondary coil into an output voltage.

According to an embodiment of the present invention, the output circuit comprises a third capacitor and a first rectifying unit. The third capacitor comprises a first terminal and a second terminal. The third capacitor is configured to generate an output voltage. The first terminal is coupled to the first secondary coil. The first rectifying unit is coupled between the first secondary coil and the second terminal. The first rectifying unit is configured to rectify some of energy of the first secondary coil to generate a third current. The third current charges the third capacitor to generate the output voltage.

According to an embodiment of the present invention, when the high-side transistor is turned on, the low-side transistor is turned off, and the first rectifying unit is turned off, the input voltage stores energy in the transformer and the first capacitor. When the high-side transistor is turned off, the low-side transistor is turned on, and the first rectifying unit is turned on, energy of the transformer and the first capacitor is transferred to the first secondary coil, so as to charge the third capacitor to generate the output voltage.

According to an embodiment of the present invention, the transformer further comprises a second secondary coil. The first secondary coil and the second secondary coil are connected in series to a second node.

According to an embodiment of the present invention, the output circuit further comprises a second rectifying unit and a choke. The second rectifying unit is coupled between the second secondary coil and the second terminal and configured to convert some of energy of the second secondary coil into a fourth current. The choke is coupled between the second node and the first terminal. The fourth current charges the third capacitor to generate the output voltage.

According to an embodiment of the present invention, when the high-side transistor is turned on, the low-side transistor is turned off, and the second rectifying unit is turned on, the input voltage stores energy in the transformer and the first capacitor, and the energy stored in the transformer is transferred to the second secondary coil through the primary coil, so as to charge the third capacitor to generate the output voltage. When the high-side transistor is turned off, the low-side transistor is turned on, and the first rectifying unit is turned on, the energy of the transformer and the first capacitor is transferred to the first secondary coil through the primary coil, so as to charge the third capacitor to generate the output voltage.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a circuit diagram showing a power converter in accordance with an embodiment of the present invention;

FIG. 2 is a circuit diagram showing a power converter in accordance with another embodiment of the present invention;

FIG. 3 is a circuit diagram showing a power converter in accordance with another embodiment of the present invention; and

FIG. 4 is a circuit diagram showing a power converter in accordance with another embodiment of the present invention.

### DETAILED DESCRIPTION OF THE INVENTION

The following description is made for the purpose of illustrating the general principles of the disclosure and should not be taken in a limiting sense. The scope of the disclosure is determined by reference to the appended claims.

In the following detailed description, for purposes of explanation, numerous specific details and embodiments are set forth in order to provide a thorough understanding of the present disclosure. The use of like and/or corresponding numerals in the drawings of different embodiments does not suggest any correlation between different embodiments.

In addition, in some embodiments of the present disclosure, terms concerning attachments, coupling and the like, such as “connected” and “interconnected,” refer to a relationship wherein structures are secured or attached to one another either directly or indirectly (for example, electrically connection) via intervening structures, as well as both movable or rigid attachments or relationships, unless expressly described otherwise.

In addition, in this specification, relative spatial expressions are used. For example, “lower”, “bottom”, “higher” or “top” are used to describe the position of one element relative to another. It should be appreciated that if a device is flipped upside down, an element that is “lower” will become an element that is “higher”.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another element, component, region, layer or section. Thus, a first element, component, region, layer, portion or section in the specification could be termed a second element, component, region, layer, portion or section in the claims without departing from the teachings of the present disclosure.

It should be understood that this description of the exemplary embodiments is intended to be read in connection with the accompanying drawings, which are to be considered part of the entire written description. The drawings are not drawn to scale. In addition, structures and devices are shown schematically in order to simplify the drawing.

The terms “approximately”, “about” and “substantially” typically mean a value is within a range of +/−20% of the stated value, more typically a range of +/−10%, +/−5%, +/−3%, +/−2%, +/−1% or +/−0.5% of the stated value. The stated value of the present disclosure is an approximate value. Even there is no specific description, the stated value still includes the meaning of “approximately”, “about” or “substantially”.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In addition, in some embodiments of the present disclosure, terms concerning attachments, coupling and the like, such as “connected” and “interconnected,” refer to a relationship wherein structures are secured or attached to one another either directly or indirectly (for example, electrically connection) via intervening structures, as well as both movable or rigid attachments or relationships, unless expressly described otherwise.

In the drawings, similar elements and/or features may have the same reference number. Various components of the same type can be distinguished by adding letters or numbers after the component symbol to distinguish similar components and/or similar features.

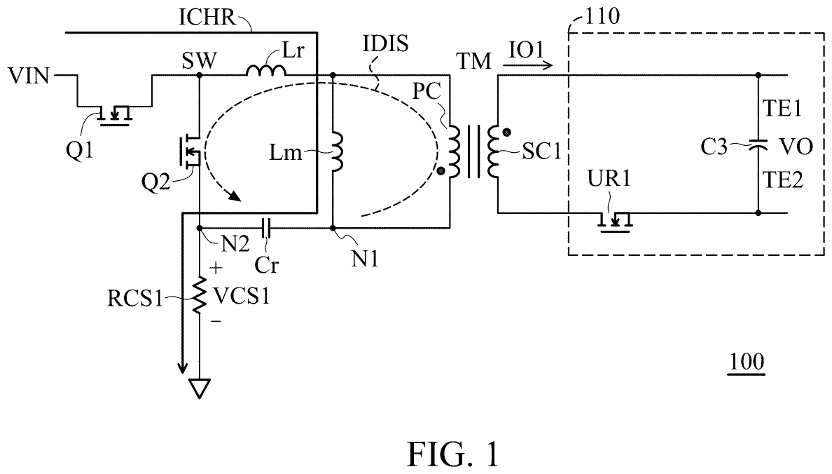

FIG. 1 is a circuit diagram showing a power converter in accordance with an embodiment of the present invention. As shown in FIG. 1, the power converter 100 includes a high-side transistor Q1, a low-side transistor Q2, a transformer TM, a first capacitor C1, a first current detection resistor RCS1, and an output circuit 110. According to an embodiment of the present invention, the power converter 100 may be an asymmetrical half-bridge flyback power converter.

The high-side switch Q1 is coupled between the input voltage VIN and the switching node SW, and the low-side switch Q2 is coupled between the switching node SW and the second node N2. The transformer TM includes a primary coil PC and a first secondary coil SC1. The primary coil PC is equivalent to a leakage inductance Lr and a magnetizing inductance Lm, and the leakage inductance Lr and the magnetizing inductance Lm are connected in series between the switching node SW and the first node N1. According to some embodiments of the present invention, the transformer TM provides the energy stored in the primary coil PC to the first secondary coil SC1. The first capacitor C1 is coupled between the first node N1 and the second node N2, and the first current detection resistor RCS1 is coupled between the second node N2 and the ground.

As shown in FIG. 1, the output circuit 110 is electrically connected across both ends of the first secondary coil SC1 to convert the energy stored in the transformer TM into the output voltage VO. The output circuit 110 includes a third capacitor C3 and a first rectifying unit UR1. The third capacitor C3 includes a first terminal TE1 and a second terminal TE2 for generating the output voltage VO. The first terminal TE1 is directly coupled to the first secondary coil SC1. The first rectifying unit UR1 is coupled between the first secondary coil SC1 and the second terminal TE2 and is configured to provide the first output current IO1 from the first secondary coil SC1 to the third capacitor C3 to generate the output voltage VO.

According to an embodiment of the present invention, the first rectifying unit UR1 may be a rectifying diode. According to another embodiment of the present invention, the first rectifying unit UR1 may be a transistor turned on and off by a gate voltage. According to other embodiments of the present invention, the first rectifying unit UR1 may be any known or unknown rectifying element. In the following embodiments, the first rectifying unit UR1 is explained by taking a transistor that is turned on and off by the gate voltage as an example, which is not intended to be limited thereto.

According to an embodiment of the present invention, when the transformer TM is completely demagnetized, the high-side transistor Q1 is turned on, the low-side transistor Q2 is turned off, and the first rectifying unit UR1 is turned off, so that the input voltage VIN charges the transformer TM and the first capacitor C1 through the high-side transistor Q1. According to an embodiment of the present invention, when the high-side transistor Q1 is turned on, the charge current ICHR generated by the input voltage VIN flows through the leakage inductor Lr, the magnetizing inductor Lm, the first capacitor C1 and the first current detection resistor RCS1 to the ground, so as to store energy in the magnetizing inductor Lm and the first capacitor C1.

According to another embodiment of the present invention, when the high-side transistor Q1 is turned off, the low-side transistor Q2 is turned on, and the first rectifying unit UR1 is turned on, the energy stored in the magnetizing inductor Lm is transferred to the first secondary coil SC1 through the turns ratio of the transformer TM, thereby generating the first output current IO1. In addition, the energy stored in the first capacitor C1 generates a discharge current IDIS, which is also transferred to the first secondary coil SC1 through the turns ratio of the transformer TM, thereby generating the first output current IO1. At the same time, the turned-on first rectifying unit UR1 provides the first output current IO1 generated by the first secondary coil SC1 to charge the third capacitor C3, thereby generating the output voltage VO.

As shown in FIG. 1, since the charge current ICHR generated by the input voltage VIN passes through the first current detection resistor RCS1 to generate the first current detection voltage VCS1, the magnitude of the charge current ICHR can be obtained by measuring the voltage across the first current detection resistor RCS1. However, since the discharge current IDIS does not flow through the first current detection resistor RCS1, the magnitude of the discharge current IDIS cannot be obtained by the first current detection voltage VCS1.

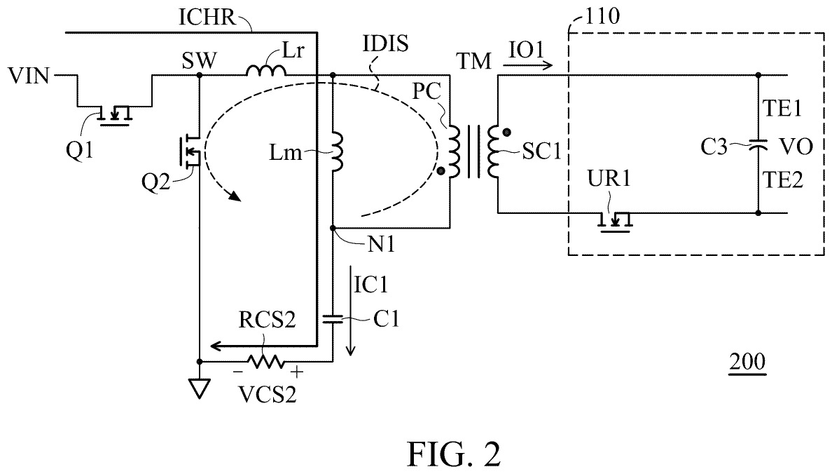

FIG. 2 is a circuit diagram showing a power converter in accordance with another embodiment of the present invention. Comparing the power converter 200 in FIG. 2 with the power converter 100 in FIG. 1, the first current detection circuit RCS1 in FIG. 1 is replaced with the second current detection circuit RCS2, and the low-side transistor Q2 is modified to be coupled between the switching node SW and the ground. According to an embodiment of the present invention, the power converter 200 may be a non-synchronous half-bridge flyback converter.

As shown in FIG. 2, since both the charge current ICHR and the discharge current IDIS flow through the second current detection resistor RCS2, the second current detection voltage VCS2 across the second current detection resistor RCS2 can be measured to obtain the magnitudes of the charge current ICHR and the discharging current IDIS. However, since both the charge current ICHR and the discharging current IDIS are large currents, the power loss caused by the second current detection resistor RCS2 is very large, thereby significantly reducing the overall conversion efficiency of the power converter 200. In addition, since the second current detection resistor RCS2 generates significant power loss, the second current detection resistor RCS2 must consider heat dissipation issues, thereby causing trouble in circuit design and causing the cost of extra devices. Therefore, there is a need for a more efficient current detection method to improve the conversion efficiency of the power converter.

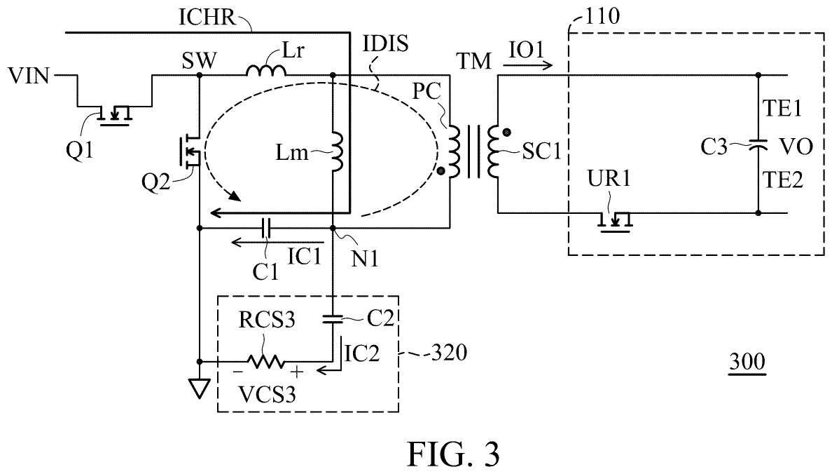

FIG. 3 is a circuit diagram showing a power converter in accordance with another embodiment of the present invention. Comparing the power converter 300 in FIG. 3 with the power converter 200 in FIG. 2, the second current detection resistor RCS2 in FIG. 2 is replaced by a current detection circuit 320, where the current detection circuit 320 and the first capacitor C1 are connected in parallel and coupled between the first node N1 and the ground.

As shown in FIG. 3, the current detection circuit 320 includes a second capacitor C2 and a third current detection resistor RCS3. The second capacitor C2 is coupled to the first node N1, and the third current detection resistor RCS3 is coupled between the second capacitor C2 and the ground. In other words, the second capacitor C2 and the third current detection resistor RCS3 are connected in series between the first node N1 and the ground, and the second capacitor C2 and the third current detection resistor RCS3, which are connected in series, are connected in parallel with the first capacitor C1.

According to an embodiment of the present invention, the capacitance value of the first capacitor C1 is N times the capacitance value of the second capacitor C2, where N is any positive number. When N is very large, the second capacitor current IC2 is much smaller than the first capacitor current IC1, so that the third current detection voltage VCS3 generated by the third current detection resistor RCS3 is much smaller than the voltage cross the second capacitor C2. When N is large enough to make the third current detection voltage VCS3 negligible, the first capacitor current IC1 is approximately N times the second capacitor current IC2. In other words, by selecting the capacitance value of the first capacitor C1 to be a proportion of the capacitance value of the second capacitor C2, the second capacitor current IC2 flowing through the third current detection resistor RCS3 can be reduced, thereby reducing the power loss caused by the current sensing resistor RCS3.

For example, it is assumed that the first capacitor current IC1 flowing through the first capacitor C1 in FIG. 2 and FIG. 3 is both I, and the second current detection resistor RCS2 is R. The second current detection voltage VCS2 in FIG. 2 is equal to I×R. As shown in FIG. 3, since the second capacitor current IC2 is approximately 1/N of the first capacitor current IC1, and in order to maintain the third current detection voltage VCS3 equal to the second current detection voltage VCS2, the third current detection resistor RCS3 in FIG. 3 should be N times the second current detection resistor RCS2. That is, the resistance value of the third current detection resistor RCS3 isN. R. The power consumption of the third current detection resistor RCS3 is as shown in Eq. 1:

$$\\ \begin{matrix}IC {3}^{2} \times RC 3 = {( \frac{I}{N} )}^{2} \times ( N \cdot R ) \\ = \frac{{I}^{2} R}{N}\end{matrix} \qquad ( Eq . 1 )$$

The power consumption of the second current detection resistor RCS2 is as shown in Eq. 2:

$$IC {2}^{2} \times RC 2 = {I}^{2} R \qquad ( Eq . 2 )$$

Comparing Eq. 1 with Eq. 2, the power consumption of the third current detection resistor RCS3 is 1/N of the power consumption of the second current detection resistor RCS2. When N is large, the power consumption of the third current detection resistor RCS3 can be significantly reduced, thereby significantly improving the conversion efficiency of the power converter 300.

In addition, since both the second current detection resistor RCS2 and the third current detection resistor RCS3 have a limitation of maximum power consumption, multiple second current detection resistors RCS2 often need to be connected in parallel to share the power consumption, so as to avoid thermal runaway phenomenon causing an increase in component costs.

For example, it is assumed that the maximum power consumption of a resistive element is 0.25 W, and that the power consumption generated by the second current detection resistor RCS2 is 0.5 W. In order to operate the resistor within a safe range, five resistors with 0.25 W maximum power consumption are chosen to be connected in parallel to form the second current detection resistor RCS2.

In other words, five resistors with a maximum power consumption of 0.25 W are configured to share the 0.5 W power consumption to avoid thermal runaway of the resistive elements. Assuming that N is 50, it means that the power consumption generated by the third current detection resistor RCS3 is only 0.01 W. At this time, only one resistor with a maximum power consumption of 0.25 W is required.

Furthermore, the power converter 300 in FIG. 3 further includes a second capacitor C2 compared to the power converter 200 in FIG. 2. Therefore, the power converter 300 requires an additional capacitor component to meet the needs of the second capacitor C2. It is assumed that the required area and component cost of a resistor and a capacitor are identical. The power converter 300 in FIG. 3 requires one resistor and one capacitor, while the power converter 200 in FIG. 2 requires five resistors.

Therefore, the power converter 300 in FIG. 3 saves the circuit area and component cost of three resistors compared to the power converter 200 in FIG. 2. In other words, compared to the power converter 200 in FIG. 2, the power converter 300 in FIG. 3 not only significantly reduces power loss and improves the overall conversion efficiency, but also reduces the component costs and circuit area required for a power converter.

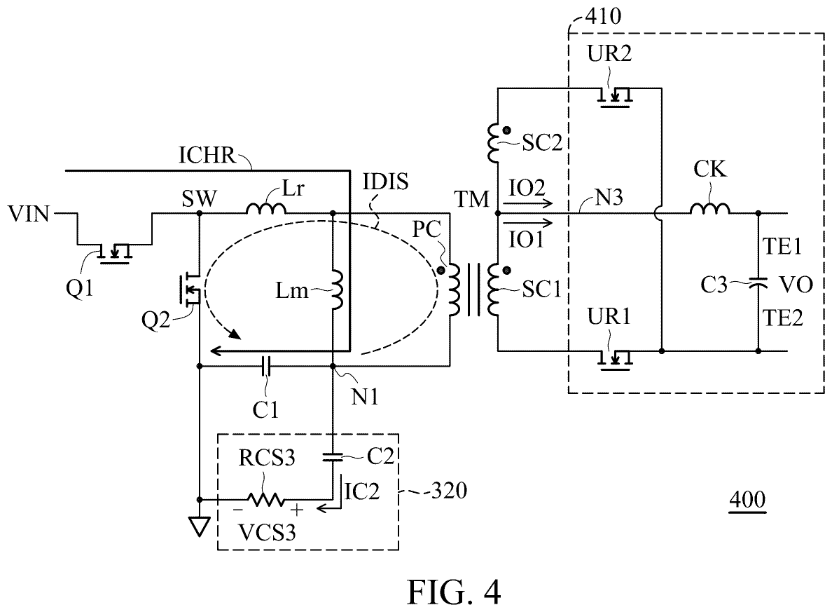

FIG. 4 is a circuit diagram showing a power converter in accordance with another embodiment of the present invention. Comparing the power converter 400 in FIG. 4 with the power converter 300 in FIG. 3, the power converter 400 further includes a second secondary coil SC2 and an output circuit 410, where the output circuit 410 further includes a second rectifying unit UR2 and a choke CK, compared to the output circuit 110 in FIG. 3.

As shown in FIG. 4, the first secondary coil SC1 and the second secondary coil SC2 are connected in series to the third node N3, and the second rectifying unit UR2 is coupled between the second secondary coil SC2 and the second end TE2. The choke coil CK is coupled between the third node N3 and the first terminal TE1 to reduce the influence of high-frequency noise.

According to an embodiment of the present invention, the second rectifying unit UR2 may be a rectifying diode. According to another embodiment of the present invention, the second rectifying unit UR2 may be a transistor which is turned on and off by a gate voltage. According to other embodiments of the present invention, the second rectifying unit UR2 may be any known or unknown rectifying element. In the embodiment of FIG. 4, the second rectifying unit UR2 is explained by taking a transistor that is turned on and off by the gate voltage as an example, but is not intended to be limited thereto.

According to an embodiment of the present invention, when the high-side transistor Q1 is turned on, the low-side transistor Q2 is turned off, and the second rectifying unit UR2 is turned on, the input voltage VIN stores energy in the transformer TM and the first capacitor C1, the energy stored in the transformer TM and the first capacitor C1 is transferred to the second secondary coil SC2 through the transformer TM, so that the second secondary coil SC2 generates the second output current IO2 charging the third capacitor C3 to generate the output voltage VO.

According to another embodiment of the present invention, when the high-side transistor Q1 is turned off, the low-side transistor Q2 is turned on, and the first rectifying element UR1 is turned on, the energy stored in the transformer TM and the first capacitor C1 is transferred to the first secondary coil SC1 through the transformer TM, so that the first secondary coil SC1 generates the first output current IO1 charging the third capacitor C3 to generate the output voltage VO.

In other words, the power loss generated by the third current detection resistor RCS3 of the current detection circuit 320 in the power converter 400 is reduced by selecting the ratio of the first capacitor C1 and the second capacitor C2, thereby improving the overall conversion efficiency and reducing component costs and circuit area. In addition, the first secondary coil SC1 outputs a part of the energy stored in the transformer TM as the first output current IO1 to charge the third capacitor C3, and the second secondary coil SC2 outputs another part of the energy stored in the transformer TM as the second output current IO2 to charge the third capacitor C3, thereby improving the conversion efficiency of the power converter 400. Furthermore, the power converter 400 further includes a second secondary coil SC2 and a second rectifying unit UR2 to generate an additional second output current IO2 to further improve the conversion efficiency.

The present invention proposes power converters and current detection circuits thereof. By mirroring a small current path in parallel to a large current path, it not only helps to significantly reduce the power loss caused by the current detection resistor, but also reduces component costs and circuit area. The accuracy of current detection is maintained as well.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A power converter, comprising:
a high-side transistor, coupled between an input voltage and a switching node;
a low-side transistor, coupled between the switching node and a ground;
a transformer, comprising a primary coil, wherein the primary coil is coupled between the switching node and a first node;
a first capacitor, coupled between the first node and the ground; and
a current detection circuit, connected in parallel with the first capacitor and comprising:
a second capacitor, coupled to the first node; and
a current detection resistor, coupled between the second capacitor and the ground.

2. The power converter as claimed in claim 1, wherein the power converter is an asynchronous half-bridge flyback converter;
wherein the power converter acknowledges a current flowing through the transformer and the first capacitor based on a voltage across the current detection resistor.

3. The power converter as claimed in claim 1, wherein a first current flows through the first capacitor, and a second current flows through the second capacitor;
wherein a first ratio of the first current to the second current is equal to a second ratio of the first capacitor to the second capacitor;
wherein the first current exceeds the second current, and a capacitance value of the first capacitor exceeds a capacitance value of the second capacitor.

4. The power converter as claimed in claim 1, wherein the transformer comprises a first secondary coil.

5. The power converter as claimed in claim 4, further comprising:
an output circuit, coupled to the first secondary coil and configured to convert energy stored in the first secondary coil into an output voltage.

6. The power converter as claimed in claim 5, wherein the output circuit comprises:
a third capacitor, comprising a first terminal and a second terminal and configured to generate an output voltage, wherein the first terminal is coupled to the first secondary coil; and
a first rectifying unit, coupled between the first secondary coil and the second node and configured to rectify some of energy of the first secondary coil into a third current;
wherein the third current charges the third capacitor to generate the output voltage.

7. The power converter as claimed in claim 6, wherein when the high-side transistor is turned on, the low-side transistor is turned off, and the first rectifying unit is turned off, the input voltage stores energy in the transformer and the first capacitor;
wherein when the high-side transistor is turned off, the low-side transistor is turned on, and the first rectifying unit is turned on, energy stored in the transformer and the first capacitor is transferred to the first secondary coil through the primary coil to charge the third capacitor to generate the output voltage.

8. The power converter as claimed in claim 6, wherein the transformer further comprises a second secondary coil;
wherein the first secondary coil and the second secondary coil are connected in series to a second node.

9. The power converter as claimed in claim 8, wherein the output circuit further comprises:
a second rectifying unit, coupled between the second secondary coil and the second terminal and configured to rectify some of energy of the second secondary coil into a fourth current; and
a choke, coupled between the second node and the first terminal;
wherein the fourth current charges the third capacitor to generate the output voltage.

10. The power converter as claimed in claim 9, wherein when the high-side transistor is turned on, the low-side transistor is turned off, and the second rectifying unit is turned on, the input voltage stores energy in the transformer and the first capacitor, and the energy stored in the transformer is transferred to the second secondary coil through the primary coil, so as to charge the third capacitor to generate the output voltage;
wherein when the high-side transistor is turned off, the low-side transistor is turned on, and the first rectifying unit is turned on, the energy of the transformer and the first capacitor is transferred to the first secondary coil through the primary coil, so as to charge the third capacitor to generate the output voltage.

11. A current detection circuit adapted to a power converter, wherein the power converter comprises a high-side transistor coupled between an input voltage and a switching node, a low-side transistor coupled between the switching node and a ground, a transformer comprising a primary coil, and a first capacitor coupled to the ground, wherein the primary coil is coupled between the switching node and the first capacitor, wherein the current detection circuit comprises:
a second capacitor, coupled to the first node; and
a current detection resistor, coupled between the second capacitor and the ground.

12. The current detection circuit as claimed in claim 11, wherein the power converter is an asynchronous half-bridge flyback converter;
wherein the power converter acknowledges a current flowing through the transformer and the first capacitor based on a voltage across the current detection resistor.

13. The current detection circuit as claimed in claim 11, wherein a first current flows through the first capacitor, and a second current flows through the second capacitor;
wherein a first ratio of the first current to the second current is equal to a second ratio of a capacitance value of the first capacitor to a capacitance value of the second capacitor;
wherein the first current exceeds the second current, and the capacitance value of first capacitor exceeds the capacitance value of the second capacitor.

14. The current detection circuit as claimed in claim 11, wherein the transformer comprises a first secondary coil.

15. The current detection circuit as claimed in claim 14, wherein the power converter further comprises an output circuit;
wherein the output circuit is coupled to the first secondary coil and configured to convert energy of the first secondary coil into an output voltage.

16. The current detection circuit as claimed in claim 15, wherein the output circuit comprises a third capacitor and a first rectifying unit;
wherein the third capacitor comprises a first terminal and a second terminal and the third capacitor is configured to generate an output voltage;
wherein the first terminal is coupled to the first secondary coil;
wherein the first rectifying unit is coupled between the first secondary coil and the second terminal and the first rectifying unit is configured to rectify some of energy of the first secondary coil to generate a third current;
wherein the third current charges the third capacitor to generate the output voltage.

17. The current detection circuit as claimed in claim 16, wherein when the high-side transistor is turned on, the low-side transistor is turned off, and the first rectifying unit is turned off, the input voltage stores energy in the transformer and the first capacitor;
wherein when the high-side transistor is turned off, the low-side transistor is turned on, and the first rectifying unit is turned on, energy of the transformer and the first capacitor is transferred to the first secondary coil, so as to charge the third capacitor to generate the output voltage.

18. The current detection circuit as claimed in claim 16, wherein the transformer further comprises a second secondary coil;
wherein the first secondary coil and the second secondary coil are connected in series to a second node.

19. The current detection circuit as claimed in claim 18, wherein the output circuit further comprises a second rectifying unit and a choke;
wherein the second rectifying unit is coupled between the second secondary coil and the second terminal and configured to convert some of energy of the second secondary coil into a fourth current;
wherein the choke is coupled between the second node and the first terminal;
wherein the fourth current charges the third capacitor to generate the output voltage.

20. The current detection circuit as claimed in claim 19, wherein when the high-side transistor is turned on, the low-side transistor is turned off, and the second rectifying unit is turned on, the input voltage stores energy in the transformer and the first capacitor, the energy stored in the transformer is transferred to the second secondary coil through the primary coil, so as to charge the third capacitor to generate the output voltage;
wherein when the high-side transistor is turned off, the low-side transistor is turned on, and the first rectifying unit is turned on, the energy of the transformer and the first capacitor is transferred to the first secondary coil through the primary coil, so as to charge the third capacitor to generate the output voltage.
